(19) United States
(12) Patent Application Publication
(10) Pub. No.: US 2023/0131168 A1
(43) Pub. Date: Apr. 27, 2023

(54) PROCESSING METHOD FOR FLUORINATION OF FLUORINATION-TARGET COMPONENT AND FLUORINATED COMPONENT OBTAINED THEREBY

(71) Applicant: WONIK QNC Corporation, Gumi-si (KR)

(72) Inventors: Yoonjae YU, Yongin-si (KR); Seungyoung Oh, Hwaseong-si (KR); Eunyoung Choi, Hwaseong-si (KR); Joohee Jang, Hwaseong-si (KR); Soyoung Choi, Anseong-si (KR)

(73) Assignee: WONIK QNC Corporation, Gumi-si (KR)

(21) Appl. No.: 17/955,561

(22) Filed: Sep. 29, 2022

(30) Foreign Application Priority Data
Oct. 21, 2021 (KR) 10-2021-0141182

(51) Int. Cl. C23C 8/36; C23C 8/08

(52) U.S. Cl. CPC C23C 8/36; C23C 8/08

(57) ABSTRACT

Disclosed are a processing method for fluorination of a fluorination-target component, which may realize high density and high strength by forming a fluoride coating based on atmospheric pressure high-frequency plasma on various components for semiconductor processes and, at the same time, may significantly increase productivity, and in particular, may ensure normal etch rate in a large-area semiconductor fabrication system, and a fluorinated component obtained by the method.

### BACKGROUND

### Technical Field

The present disclosure relates to a processing method for fluorination of a fluorination-target component and a fluorinated component obtained thereby, and more particularly, to a processing method for fluorination of a fluorination-target component, which may realize high density and high strength by forming a fluoride coating based on atmospheric pressure high-frequency plasma on various components for semiconductor processes and, at the same time, may significantly increase productivity by shortening aging time in a backup step, and in particular, may ensure normal etch rate in a large-area semiconductor fabrication system, and a fluorinated component obtained by the method.

### Related Art

A semiconductor dry etching system needs to be shutdown (down) for system inspection or components replacement (maintenance) which is performed on a regular basis, and then should undergo a backup process for normal operation of the semiconductor fabrication system before the system is restarted.

The backup process in the semiconductor dry etching system includes several steps, such as a step of removing water vapor in the system (out-gassing step), a step of reducing contaminant particles in the system, an aging step for fluorination in the system, and a step of verifying the quality of a sample using a mass-produced wafer (In Fab. Data).

Among these steps, the aging step is performed to create a fluoride atmosphere capable of realizing normal etch rate in the semiconductor dry etching system. In this aging step, a certain level of corrosive gas is applied to the surface of a plasma-resistant coating (Al₂O₃, Y₂O₃, YAG, etc.) formed inside the system, thereby forming a fluoride layer having a YOF composition and a thickness of several nm to several hundred nm on the surface.

If the fluoride atmosphere is not sufficiently created inside the semiconductor dry etching system, a problem may arise in that the time to repeatedly perform the aging step increases, and thus the operating time of the semiconductor fabrication system is greatly reduced, resulting in a decrease in the productivity of the semiconductor fabrication system and an increase in fabrication cost.

Meanwhile, as an example of a conventional method of forming a fluoride layer, there is known a method in which a component to be fluorinated is placed in a vacuum chamber, and then low-pressure vacuum plasma such as CF₄, SF₆ or NF₃, which is a gas containing fluorine, is generated and the surface of the component is fluorinated by fluorine-containing radicals (“Fabrication, characterization, and fluorine-plasma exposure behavior of dense yttrium oxyfluoride ceramic”, T Tsunoura et al, Japanese Journal of Applied Physics 56, 06HC02 (2017), “Fluorination mechanisms of Al₂O₃ and Y₂O₃ surfaces irradiated by high-density CF₄/O₂ and SF₆/O₂ plasmas”, K Miwa et al, J Vac Sci Technol A 27(4), July/August 2009).

However, this method has disadvantages in that it is required to construct a vacuum chamber and vacuum devices, which is disadvantageous to mass production and economic efficiency, and since a low-pressure plasma process is used, the density of fluorine-containing radicals is low and the fluorination rate is low, thus lowering productivity.

As another example, there is known a method in which a component to be fluorinated is immersed in a solution of HF, SF₄, CHF₃ or the like, and then the surface of the component is fluorinated by raising the temperature to about 250° C. (“Preparation of Fluorinated-Alumina”, E Kemnitz et al, “Efficient Preparations of Fluorine Compounds”, Edited by H W Roesky, 2013, 442).

However, this method has disadvantages in terms of process safety because it uses a hazardous solution in handling and treatment processes.

As still another example, U.S. Pat. No. 8,206,829 and/or US Patent Publication No. 2017/0114440 is known. The above document discloses a method of coating a surface of a component with a powder material such as AlF₃, YF₃, AlOF, or YOF by a method such as plasma spraying.

However, this method has disadvantages in that the price of AlF₃ or YF₃, which is a coating raw material used to form a coating on a ceramic protective layer such as alumina (Al₂O₃) or yttria (Y₂O₃), is very high, and the raw material suppliers are limited, and thus the supply of the raw material is not smooth, leading to reduced economic efficiency.

### SUMMARY

Accordingly, the present disclosure has been made in order to solve the above-described problems occurring in the prior art, and an object of the present disclosure is to provide a processing method for fluorination of a fluorination-target component, which may realize high density and high strength by forming a fluoride coating based on an atmospheric pressure high-frequency plasma source on various components for semiconductor processes and, at the same time, may significantly increase productivity by shortening aging time in a backup process, and in particular, may ensure normal etch rate in a large-area semiconductor fabrication system, and a fluorinated component obtained by the method.

Objects to be solved by the present disclosure are not limited to those mentioned above, and other objects not mentioned herein will be clearly understood by those skilled in the art from the following description.

In accordance with one aspect of the present disclosure for achieving the objects and other features of the present disclosure, there is provided a processing method for fluorinating the surface of a fluorination-target component, the method including: a first step of placing the fluorination-target component in a processing chamber having a plasma reaction space; a second step of introducing a mixed gas into the processing chamber, the mixed gas being composed of a discharge gas selected from among He, Ne, Ar, Kr, and Xe, a fluorine-free reactive gas selected from among O₂, N₂, and air, and a fluorine-containing reactive gas selected from among fluorocarbons, including CF₄, C₂F₆, and C₄F₈, and nitrogen trifluoride (NF₃); a third step of supplying the mixed gas, introduced into the processing chamber, into the plasma reaction space; and a fourth step of generating plasma in the plasma reaction space by applying high-frequency power to the processing chamber, and fluorinating the surface of the fluorination-target component by the generated plasma and fluorine-containing radical gas, wherein the atmosphere in the processing chamber in the first to fourth steps is an atmospheric-pressure atmosphere.

In the processing method for fluorinating the surface of a fluorination-target component, wherein the third step comprises supplying argon (Ar) as the discharge gas, oxygen (O₂) as the fluorine-free reactive gas, and carbon tetrafluoride (CF₄) as the fluorine-containing reactive gas, and a flow rate ratio of Ar:O₂:CF₄ is 0.1 to 60:0.1 to 10:0.1 to 10.

In the processing method for fluorinating the surface of a fluorination-target component, wherein the high-frequency power in the fourth step is 300 to 400 W at a frequency of 1 to 100 MHz.

In the processing method for fluorinating the surface of a fluorination-target component, wherein a temperature inside the processing chamber is room temperature to 400° C.

In the processing method for fluorinating the surface of a fluorination-target component, wherein the third step and the fourth step are repeated.

In the processing method for fluorinating the surface of a fluorination-target component, wherein a distance between the fluorination-target component and the plasma is 2 mm to 5 mm.

In the processing method for fluorinating the surface of a fluorination-target component, wherein a fluoride coating layer on the fluorination-target component is formed to have a thickness of 150 to 200 μm.

The processing method for fluorination of a fluorination-target component according to the present disclosure and a fluorinated component obtained thereby provide the following effects.

First, the present disclosure provides the effect of providing a new-concept component fluorination technology capable of fluoridation processing of a component using specific process factors through high-frequency plasma at room temperature and atmospheric pressure for a plasma-resistant coating formed on a semiconductor dry etching system.

Second, the present disclosure has the effect of improving productivity by shortening the time of the aging step, which is one of the backup processes being performed in the semiconductor dry etching system.

Third, the present disclosure has the effects of increasing productivity by increasing the rate of fluorination (process) performed in the aging step, and reducing the cost relatively while applying the present disclosure to a large-area component with high density and high strength.

The effects of the present disclosure are not limited to those mentioned above, and other problems not mentioned herein will be clearly understood by those skilled in the art from the following description.

### BRIEF DESCRIPTION OF THE DRAWINGS

FIG. 1 is a flow chart showing a processing method for fluorination of a fluorination-target component according to the present disclosure.

FIGS. 2A and 2B show the results of conducting an experiment on the flow rate ratio of Ar:O₂:CF₄ gases used in the processing method for fluorination of a fluorination-target component according to the present disclosure. Specifically, FIGS. 2A and 2B show scanning electron microscope images of the surface layer of a fluorination-target component depending on the flow rate of Ar (FIG. 2A), and a graph showing the contents of F and Al depending on the flow rate of Ar (FIG. 2B).

FIGS. 3A and 3B show the results of conducting an experiment on the flow rate ratio of Ar:O₂:CF₄ gases used in the processing method for fluorination of a fluorination-target component according to the present disclosure. Specifically, FIGS. 3A and 3B shows scanning electron microscope images of the surface layer of a fluorination-target component depending on the flow rate of O₂ (FIG. 3A), and a graph showing the contents of F and Al depending on the flow rate of O₂ (FIG. 3B).

FIGS. 4A and 4B show the results of conducting an experiment on the flow rate ratio of Ar:O₂:CF₄ gases used in the processing method for fluorination of a fluorination-target component according to the present disclosure. Specifically, FIGS. 4A and 4B show scanning electron microscope images of the surface layer of a fluorination-target component depending on the flow rate of CF₄ (FIG. 4A), and a graph showing the contents of F and Al depending on the flow rate of CF₄ (FIG. 4B).

FIGS. 5A and 5B show the results of conducting an experiment on high-frequency power in the processing method for fluorination of a fluorination-target component according to the present disclosure. Specifically, FIG. 5A shows scanning electron microscope images of the surface layer of the fluorination-target component depending on plasma power, and FIG. 5B is a graph showing the contents of F and Al depending on plasma power.

FIGS. 6A and 6B show the results of conducting an experiment on the heating temperature of the fluorination-target component in the processing method for fluorination of a fluorination-target component according to the present disclosure. Specifically, FIG. 6A shows scanning electron microscope images of the fluorination-target component depending on temperature, and FIG. 6B is a graph showing the contents of F and Al depending on temperature.

FIGS. 7A and 7B show the results of conducting an experiment on the number of repetitions of the step of supplying the mixed gas and the fluorinating step. Specifically, FIG. 7A shows scanning electron microscope images of the surface of the fluorination-target component depending on the number of repetitions, and FIG. 7B is a graph showing the contents of F and Al depending on the number of repetitions.

FIGS. 8A and 8B show the results of conducting an experiment on the distance between the fluorination-target component (base material) and the plasma in the processing method for fluorination of a fluorination-target component according to the present disclosure. Specifically, FIG. 8A shows scanning electron microscope images of the surface layer of the fluorination-target component depending on the distance, and FIG. 8B is a graph showing the contents of F and Al depending on the distance.

FIG. 9 is a table showing cross-sectional images and component analysis of a fluorination-target component depending on temperature in the processing method for fluorination of a fluorination-target component according to the present disclosure.

FIG. 10 is a table showing cross-sectional images and component analysis of a fluorination-target component depending on the number of repetitions in the processing method for fluorination of a fluorination-target component according to the present disclosure.

FIG. 11 is a table showing cross-sectional images and component analysis of a fluorination-target component depending on power in the processing method for fluorination of a fluorination-target component according to the present disclosure.

FIG. 12 is a table showing the results of X-ray photoelectron spectroscopy analysis of a fluorination-target component depending on the content of F in the processing method for fluorination of a fluorination-target component according to the present disclosure.

FIG. 13 is a table showing transmission electron microscope images and component analysis of a fluorination-target component depending on the content of F in the processing method for fluorination of a fluorination-target component according to the present disclosure.

FIG. 14 is a table showing hardness analysis of a fluorination-target component depending on the content of F in the processing method for fluorination of a fluorination-target component according to the present disclosure.

FIG. 15 depicts photographs showing the results of testing the chemical resistance of a fluorination-target component in HCL solution depending on the content of F in the processing method for fluorination of a fluorination-target component according to the present disclosure.

### DETAILED DESCRIPTION

Additional objects, features and advantages of the present disclosure may be more clearly understood from the following detailed description and the accompanying drawings.

Hereinafter, a processing method for fluorination of a fluorination-target component according to a preferred embodiment of the present disclosure will be described in detail with reference to the accompanying drawings.

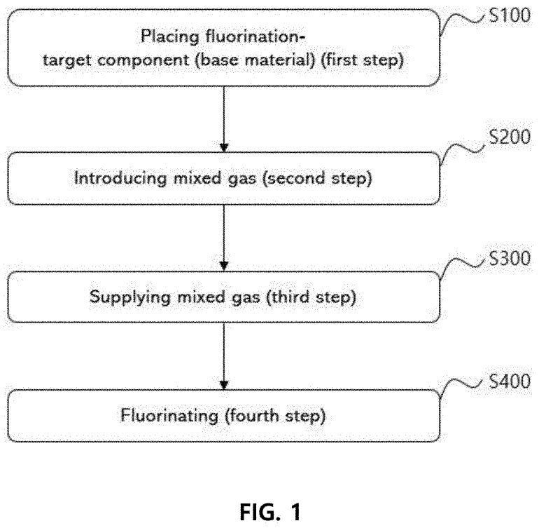

FIG. 1 is a flow chart showing a processing method for fluorination of a fluorination-target component according to the present disclosure.

The processing method for fluorination of a fluorination-target component according to the present disclosure is a processing method for fluorinating the surface of a fluorination-target component, which is used in, for example, a semiconductor process. As shown in FIG. 1, the processing method generally includes step (S100) of placing the fluorination-target component; step (S200) of introducing a mixed gas; step (S300) of supplying the mixed gas; and step (S400) of fluorinating the surface of the fluorination-target component.

Specifically, the processing method for fluorination of a fluorination-target component according to the present disclosure is a processing method for fluorinating the surface of a fluorination-target component, which is used in, for example, a semiconductor process, and as shown in FIG. 1, the processing method includes: a first step (S100) of placing the fluorination-target component in a processing chamber of a fluorination processing apparatus, which has a plasma jet outlet and a plasma reaction space, so as to face the plasma jet outlet; a second step (S200) of introducing a mixed gas into the processing chamber, the mixed gas being composed of a discharge gas selected from among He, Ne, Ar, Kr, and Xe, a fluorine-free reactive gas selected from among O₂, N₂, and air, and a fluorine-containing reactive gas selected from fluorocarbons, including CF₄, C₂F₆, and C₄F₈, and nitrogen trifluoride (NF₃); a third step (S300) of supplying the mixed gas, introduced into the processing chamber, into the plasma reaction space; and a fourth step (S400) of generating plasma in the plasma reaction space by applying high-frequency power to a metal electrode rod provided in the processing chamber, and fluorinating the surface of the fluorination-target component by jetting the generated plasma and fluorine-containing radical gas through the plasma jet outlet, wherein the atmosphere in the processing chamber in the first to fourth steps (S100 to S100) is an atmospheric-pressure atmosphere, and the third step (S300) and the fourth step (S400) are performed 1 to 10 times.

The first step (S100) of placing the fluorination-target component is a process of placing the fluorination-target component in a processing chamber of a fluorination processing apparatus, which has a plasma jet outlet and a plasma reaction space, so as to face the plasma jet outlet. In this step, the fluorination-target component is placed on a support (a support provided with a heater) located inside the processing chamber, and the door of the processing chamber is closed to isolate the interior from the outside.

The fluorination processing apparatus having the processing chamber, which is used in the step (S100) of placing the fluorination-target component, may include, for example: a metal electrode rod whose surface is insulated by an insulator; a non-conductive ceramic tube provided coaxially with the metal electrode and extending while being spaced from the metal electrode rod; a grounding tube extending around the outer circumferential surface of the non-conductive ceramic tube and electrically grounded, wherein the entire inner circumferential surface of the grounding tube is in contact with the non-conductive ceramic tube; and a plasma jet outlet head module having a plasma reaction space consisting of an annular space between the outer circumferential surface of the metal electrode rod and the inner circumferential surface of the non-conductive ceramic tube and extending in the lengthwise direction, wherein the open portion at the bottom of the annular space becomes a plasma jet outlet.

In addition, the processing chamber may include: a high-frequency power supply device configured to apply high-frequency power to the metal electrode rod and connected to the metal electrode rod through a high-frequency matching box that performs impedance matching; a gas supply unit configured to supply the mixed gas including the fluorine-containing reactive gas to the plasma reaction space; and a sample support provided at the bottom of the plasma jet outlet and on which the sample is placed.

The top of the plasma jet head module is fixed to the top of the processing chamber, the metal electrode rod is disposed to penetrate the processing chamber and extends vertically downward, the top of the metal electrode rod is connected to the high-frequency matching box, the non-conductive ceramic tube extends downward in the lengthwise direction while the top thereof is located in the gas chamber, and the mixed gas is introduced into the plasma reaction space from the processing chamber.

Next, the second step (S200) of introducing a mixed gas is a process of introducing a mixed gas into the processing chamber, the mixed gas being composed of a discharge gas selected from among He, Ne, Ar, Kr, and Xe, a fluorine-free reactive gas selected from among O₂, N₂, and air, and a fluorine-containing reactive gas selected from among fluorocarbons, including CF₄, C₂F₆, and C₄F₈, and nitrogen trifluoride (NF₃).

In step (S200) of introducing the mixed gas, the discharge gas argon (Ar), the nitrogen-free reactive gas oxygen (O₂) and the fluorine-containing reactive gas carbon tetrafluoride (CF₄) are introduced into the processing chamber from the respective gas tanks of the gas supply unit.

In this case, the mixed gas is introduced into the processing chamber while the flow rate ratio of the gases is controlled by gas flow rate controllers. In the third step (S300) of supplying the mixed gas, the mixed gas is supplied into the plasma reaction space.

Here, as the discharge gas, insert gas such as He, Ne, Kr or Xe may be used in addition to Ar gas. As the nitrogen-free reactive gas, nitrogen (N₂), air or the like may be used in addition to oxygen (O₂) gas. As the fluorine-containing gas, a carbon fluoride gas such as C₂F₆ or C₄F₈, or nitrogen trifluoride (NF₃) gas may be used in addition to CF₄ gas. However, in the present disclosure, it is preferable to use argon (Ar) gas as the discharge gas, oxygen (O₂) as the nitrogen-free reactive gas, and carbon tetrafluoride (CF₄) as the fluorine-containing reactive gas.

In addition, the flow rate ratio of Ar:O₂:CF₄ that are used in step (S200) of introducing the mixed gas is preferably 0.1 to 60:0.1 to 10:0.1 to 10, more preferably 25 to 40:0.1 to 0.4:0.3 to 1.0.

Through an experiment on the flow rate ratio of Ar:O₂:CF₄ used, the inventors of the present disclosure have found that the above-described flow rate ratio is an optimal ratio.

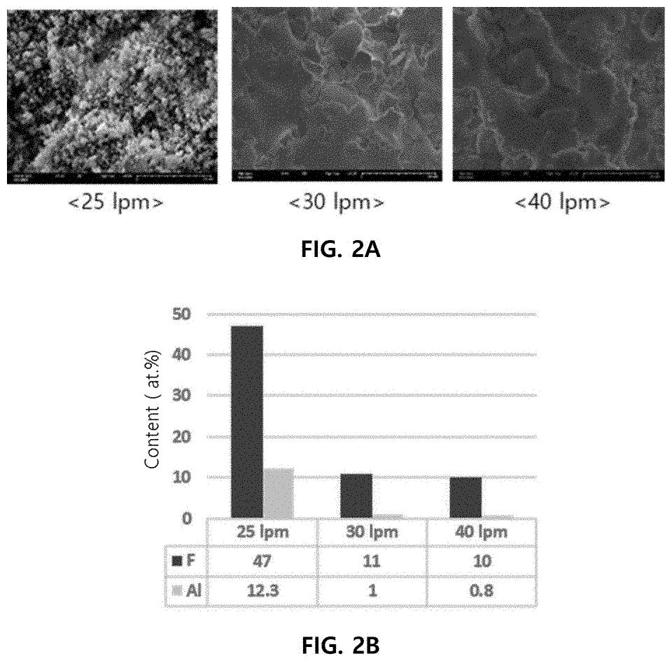

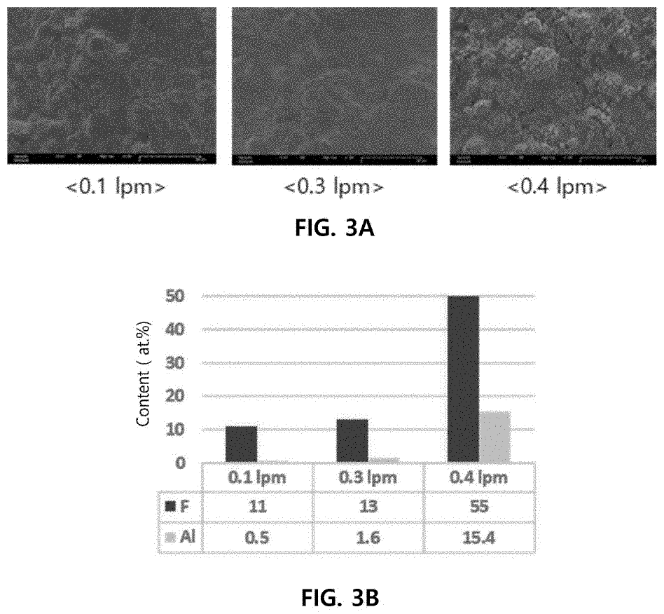

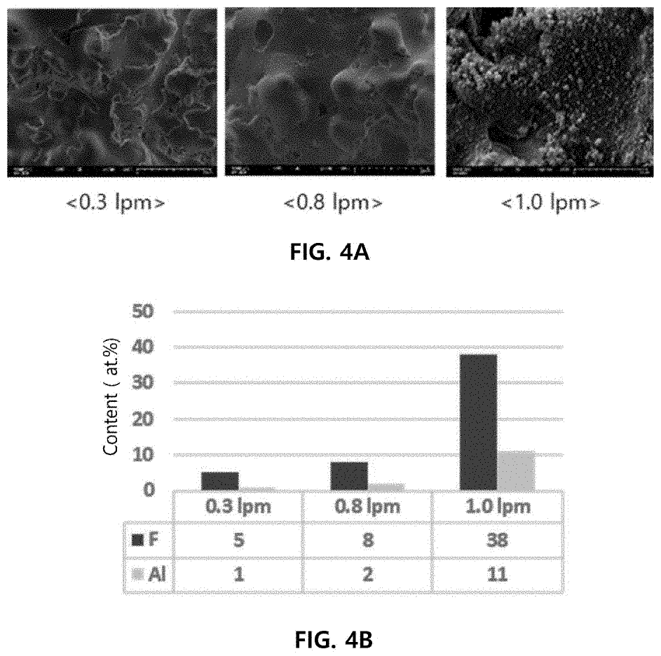

FIGS. 2A to 4 show the results of conducting experiments on the flow rate ratio of Ar:O₂:CF₄ used in the processing method for fluorination of a fluorination-target component according to the present disclosure. Specifically, FIGS. 2A and 2B show scanning electron microscope images of the surface layer of a fluorination-target component depending on the flow rate of Ar (FIG. 2A), and a graph showing the contents of F and Al depending on the flow rate of Ar (FIG. 2B), FIGS. 3A and 3B show scanning electron microscope images of the surface layer of a fluorination-target component depending on the flow rate of O₂ (FIG. 3A), and a graph showing the contents of F and Al depending on the flow rate of O₂ (FIG. 3B), and FIGS. 4A and 4B show scanning electron microscope images of the surface layer of a fluorination-target component depending on the flow rate of CF₄ (FIG. 4A), and a graph showing the contents of F and Al depending on the flow rate of CF₄ (FIG. 4B).

As shown in FIGS. 2A and 2B, the inventors of the present disclosure have found that, if the flow rate of Ar is higher than 40 lpm, some particles occur, and in particular, if the flow rate of Ar is higher than 60 lpm, a problem arises in that a considerable amount of particles occur, and if the flow rate of Ar is lower than 0.1 lpm, a problem arises in that plasma is unstable, and in particular, when the flow rate of Ar is 25 lpm or lower, plasma is stable and thus optimal fluorination processing of the fluorination-target component may be performed.

In addition, as shown in FIGS. 3A and 3B, it has been found that, if the flow rate of O₂ is higher than 0.4 lpm, a small amount of particles occur, and in particular, if the flow rate of O₂ is higher than 10 lpm, a problem arises in that a considerable amount of particles occur. Furthermore, as shown in FIGS. 4A and 4B, it has been found that, if the flow rate of CF₄ is higher than 1.0 lpm, a small amount of particle occur, and in particular, if the flow rate of CF₄ is higher than 10 lpm, a problem arises in that a considerable amount of particles occur.

Next, step (S400) of fluorinating the fluorination-target component is a process of generating plasma in the plasma reaction space by applying high-frequency power to a metal electrode rod provided in the processing chamber, and fluorinating the surface of the fluorination-target component by jetting the generated plasma and fluorine-containing radical gas through the plasma jet outlet.

In the fluorinating step (S400) in the present disclosure, the high-frequency power that is applied through the high-frequency power device is preferably 300 to 400 W at a frequency of 1 to 100 MHz.

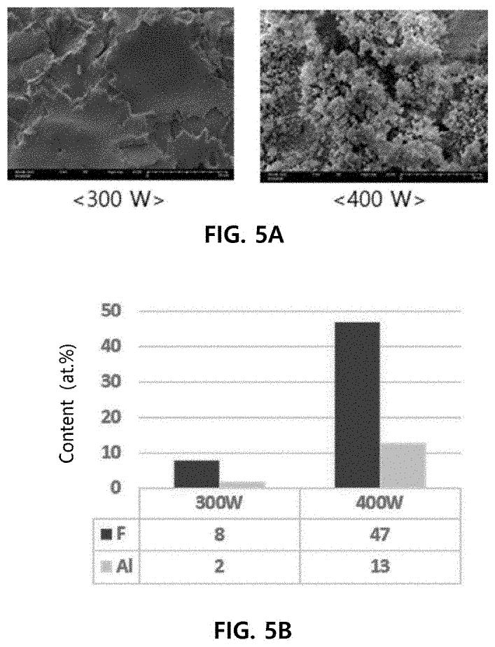

FIGS. 5A and 5B show the results of conducting an experiment on high-frequency power in the processing method for fluorination of a fluorination-target component according to the present disclosure. Specifically, FIG. 5A shows scanning electron microscope images of the surface layer of the fluorination-target component, and FIG. 5B is a graph showing the contents of F and Al.

As shown in FIGS. 5A and 5B, it has been found that, if the high-frequency power that is applied in the fluorinating step (S400) is lower than 100 W and higher than 1,000 W, problems arise in that particles occur and plasma is unstable.

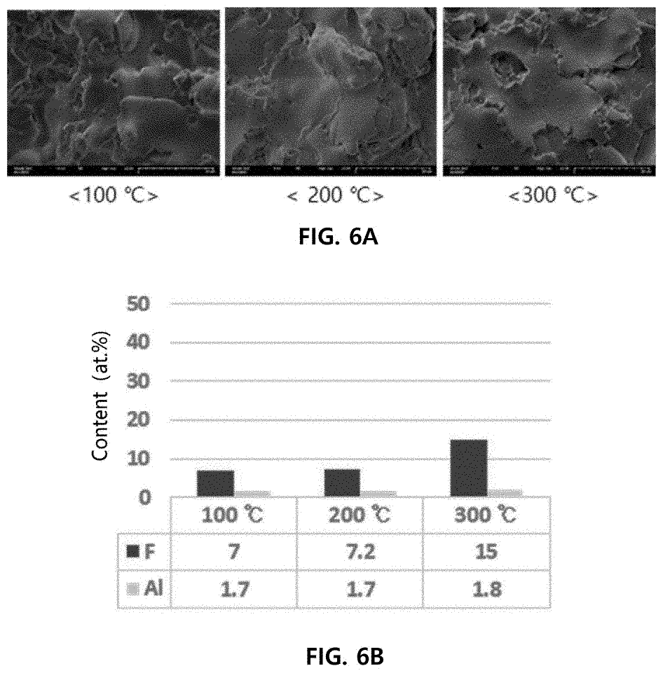

Meanwhile, in the processing method for fluorination of a fluorination-target component according to the present disclosure, the temperature inside the processing chamber, that is, the heating temperature of the fluorination-target component, is preferably room temperature to 400° C. FIGS. 6A and 6B show the results of conducting an experiment on the heating temperature of the fluorination-target component in the processing method for fluorination of a fluorination-target component according to the present disclosure. Specifically, FIG. 6A shows scanning electron microscope images of the fluorination-target component depending on temperature, and FIG. 6B is a graph showing the contents of F and Al depending on temperature.

It has been confirmed that, if the heating temperature of the fluorination-target component in the processing method for fluorination of a fluorination-target component according to the present disclosure is higher than 400° C., a problem arises in that the coating layer on the fluorination-target component is peeled or separated.

In addition, in the processing method for fluorination of a fluorination-target component according to the present disclosure, step (S300) of supplying the mixed gas and step (S400) of fluorinating the fluorination-target component are preferably repeated one or more times.

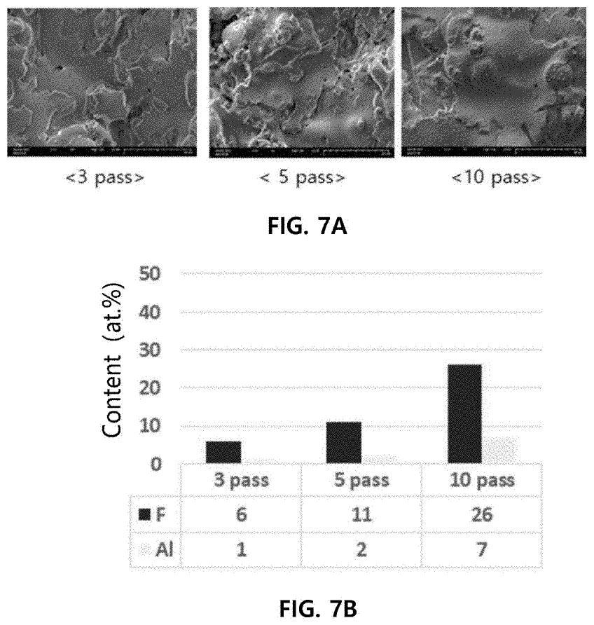

FIGS. 7A and 7B show the results of conducting an experiment on the number of repetitions of the step of supplying the mixed gas and the fluorinating step. Specifically, FIG. 7A shows scanning electron microscope images of the surface of the fluorination-target component depending on the number of repetitions, and FIG. 7B is a graph showing the contents of F and Al depending on the number of repetitions.

Here, when the number of repetitions is one or more and one cycle consists of the step of supplying the mixing gas and the fluorinating step, the pause time between cycles is preferably set to 60 seconds to 10 minutes.

Meanwhile, the inventors of the present disclosure have found that the distance between the fluorination-target component and the plasma is an important process factor in the processing method for fluorination of a fluorination-target component according to the present disclosure. The distance between the fluorination-target component to be fluorinated and the plasma is the distance from the surface of the fluorination-target component to be fluorinated to the entrance of the plasma jet outlet.

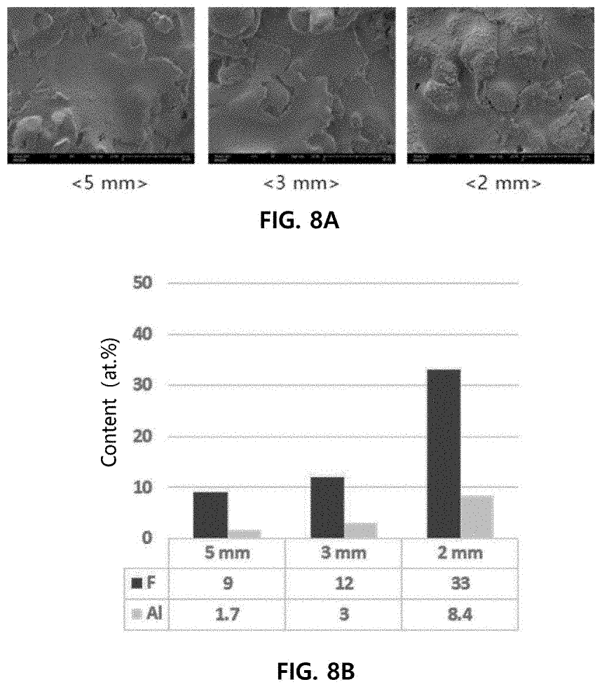

FIGS. 8A and 8B show the results of conducting an experiment on the distance between the fluorination-target component (base material) and the plasma in the processing method for fluorination of a fluorination-target component according to the present disclosure. Specifically, FIG. 8A shows scanning electron microscope images of the surface layer of the fluorination-target component depending on the distance, and FIG. 8B is a graph showing the contents of F and Al depending on the distance.

The distance between the fluorination-target component and the plasma in the processing method for fluorination of a fluorination-target component according to the present disclosure is preferably 1 mm to 50 mm.

The inventors of the present disclosure have found that, if the distance between the fluorination-target component and the plasma is less than 1 mm, problems arises in that particles occur and discharge is difficult, and if the distance between the fluorination-target component and the plasma is more than 50 mm, a problem arises in that discharging voltage needs to be increased, so a large-capacity high-frequency power supply device is required, causing increased costs.

In the processing method for fluorination of a fluorination-target component according to the present disclosure, the fluoride coating layer of the fluorination-target component is preferably formed to have a thickness of 0.001 to 10 μm.

Meanwhile, the inventors of the present disclosure evaluated process factors (power, temperature, and the number of repetitions) capable of forming a fluoride layer by allowing an Y₂O₃ coating, produced by atmospheric plasma spraying, to react with corrosive fluorine (F) gas.

The Y₂O₃ coating produced by atmospheric plasma spraying has a surface roughness of several μm due to the use of granular powder of several tens of μm as a raw fluorination-target component. In order to accurately examine the changes in surface microstructures and elements due to the fluoride coating layer after fluorination modification, the surface was mirror-polished to 0.1 μm, and then the processing method for fluorination (a new method for fluorination modification of coating) according to the present disclosure was applied to the surface.

In order to examine changes in cross-sectional microstructures in a Y₂O₃ coating produced by atmospheric plasma spraying, as well as the depth and distribution of the fluoride layer formed using the processing method for fluorination according to the present disclosure, the coating was processed by a focused ion beam and observed under a scanning electron microscope and the content of F component was analyzed using energy dispersive spectroscopy.

In addition, in order to examine the crystal phase change caused by the reaction of the Y₂O₃ coating, produced by atmospheric plasma spraying, with corrosive F gas, high-resolution X-ray diffraction analysis was performed.

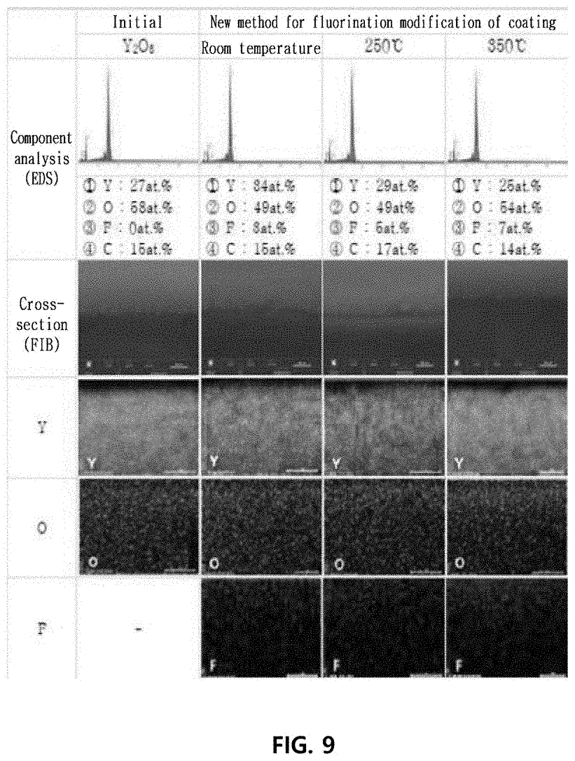

FIG. 9 is a table showing cross-sectional images and component analysis of a fluorination-target component depending on temperature in the processing method for fluorination of a fluorination-target component according to the present disclosure.

First, as a result of analyzing the cross-sectional microstructures of the Y₂O₃ coating produced by atmospheric plasma spraying method and subjected to mirror polishing, it was confirmed that micropores were hardly observed on the surface, but there were some scratches caused by the mirror polishing, and Y, O and C components were detected in amounts of 27 at. %, 58 at. % and 15 at. %, respectively.

In addition, as a result of observing microstructures in the coating processed by the focused ion beam, it could be confirmed that there were some vertical cracks due to typical volume contraction occurring in the coating formed by atmospheric plasma spraying. As a result of analyzing the component distribution inside the coating using mapping by energy dispersive spectroscopy, it could be confirmed that Y and O components were uniformly distributed throughout the coating.

Meanwhile, in order to examine the tendency of production of a fluoride layer depending on temperature in the processing method for fluorination of a fluorination-target component according to the present disclosure, a fluoride layer was formed by performing the processing method for fluorination according to the present disclosure on the Y₂O₃ coating, produced by atmospheric plasma spraying, while changing the temperature to 100, 250 and 350° C.

As a result of observing the surface microstructures in the coating after applying the processing method for fluorination according to the present disclosure, it was confirmed that the coating showed the same microstructures as the Y₂O₃ coating (produced by atmospheric plasma spraying) before applying the processing method for fluorination, indicating that the microstructures were not changed by fluorination modification, whereas F was additionally detected in addition to Y, O and C components in the coating, and the detected F increased proportionally as the temperature increased and was present in an amount of 3 to 7 at. %, suggesting that the YOF fluoride layer was effectively formed on the coating surface.

In addition, as a result of observing the microstructures in the coating processed by the focused ion beam, the YOF fluoride layer was not clearly identified near the surface of the coating. However, as a result of performing mapping by energy dispersive spectroscopy, it was confirmed that the color corresponding to the F component existed inside the coating. Furthermore, as the temperature increased, the color contrast near the surface became higher than that inside the coating. This was consistent with the fact that, as the temperature increased, the content of the F component on the coating surface increased to 3, 5 and 7 at. % as mentioned above.

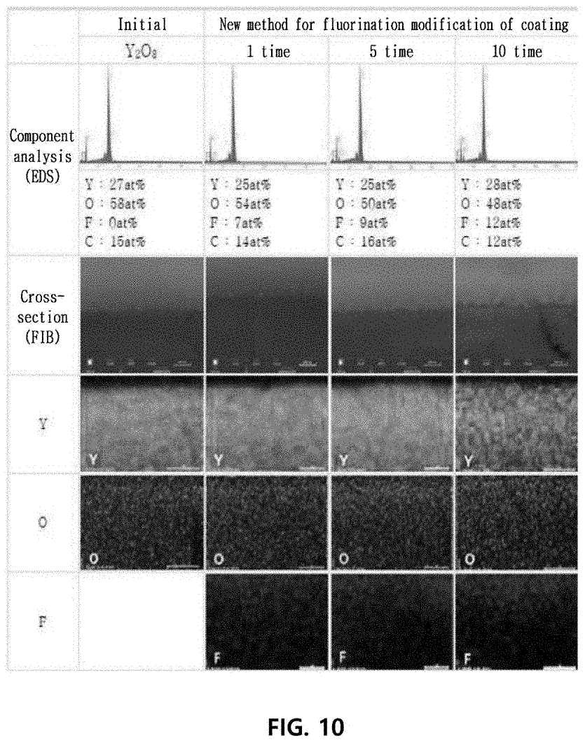

FIG. 10 is a table showing cross-sectional images and component analysis of a fluorination-target component depending on the number of repetitions in the processing method for fluorination of a fluorination-target component according to the present disclosure.

Next, in order to examine the tendency of formation of the fluoride layer depending on the number of repetitions, a fluoride layer was formed by performing the processing method for fluorination (a new method for fluorination modification of a coating) according to the present disclosure on a Y₂O₃ coating (produced by atmospheric plasma spraying) while setting the temperature to 350° C. and changing the number of repetitions to 1, 5 and 10.

In addition, as a result of observing the microstructures in the coating processed by the focused ion beam, it was confirmed that the YOF fluoride layer of the fluorination-target target was not clearly identified, like the results of conducting the experiment on the temperature. However, as a result of mapping by energy dispersive spectroscopy, it was confirmed that the color corresponding to the F component existed inside the coating, and as the number of repetitions increased, the contrast of the color on the surface was more clearly distinguished, indicating that the reaction of the F component occurred actively, and the content of F increased up to 12 at. %.

This is because as the number of repetitions increased, the time during which the coating surface was exposed to dissociated F ions increased, and thus the amount of F component diffused to the coating surface increased, thus increasing the content of F.

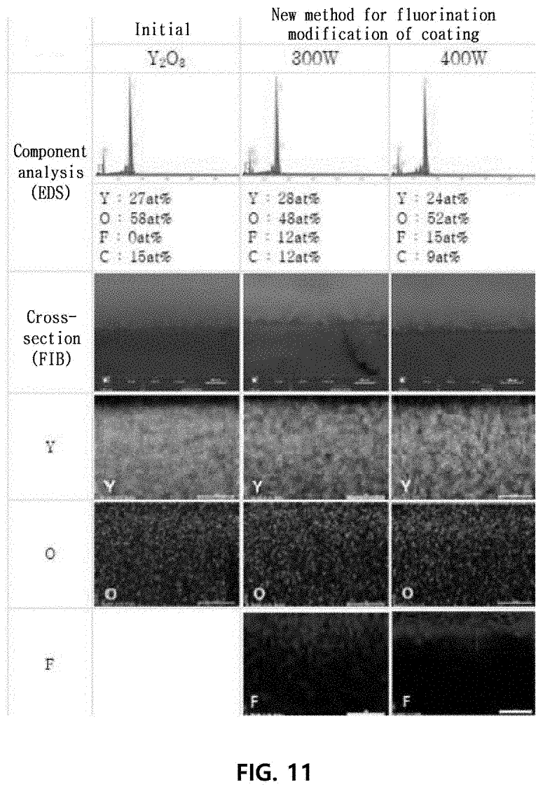

FIG. 11 is a table showing cross-sectional images and component analysis of a fluorination-target component depending on power in the processing method for fluorination of a fluorination-target component according to the present disclosure.

A fluoride layer was formed by performing the processing method for fluorination (a new method for fluorination modification of a coating) according to the present disclosure on a Y₂O₃ coating (produced by atmospheric plasma spraying) while setting the temperature to 350° C. and the number of repetitions to 10 and increasing the power from 300 W to 400 W.

It was confirmed that, as the power increased, the content of the F component increased up to 15 at. %, but the YOF fluoride layer of the fluorination-target component was not clearly identified, like the results of conducting the experiment on the temperature and the number of repetitions. In addition, as a result of mapping by energy dispersive spectroscopy, the color corresponding to the F component existed inside the coating, and as the power increased, the color contrast on the surface was more clearly distinguished.

This is also because as the power increased, the density of dissociated F radicals increased while the decomposition of the F-based corrosive gas is further accelerated, thus the reactivity of the coating surface increased, thereby increasing the content of F.

Subsequently, the inventors of the present disclosure selected F contents of 5, 9 and 15 at. % as determined by analyzing the Y₂O₃ coating (produced by atmospheric plasma spraying) while changing the temperature, repetition number and power factors, and performed X-ray photoelectron spectroscopy and transmission electron microscopy in order to examine the depth-dependent component changes and thickness of the YOF fluoride layer of the fluorination-target component.

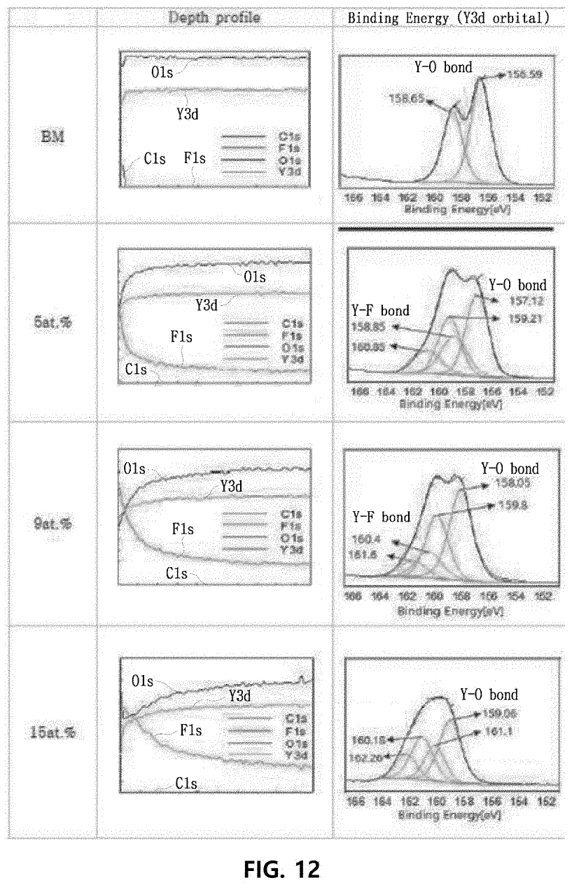

FIG. 12 is a table showing the results of X-ray photoelectron spectroscopy analysis of a fluorination-target component depending on the content of F in the processing method for fluorination of a fluorination-target component according to the present disclosure.

First, using X-ray photoelectron spectroscopy, changes in the content of F component depending on the depth from the surface to the inside of the coating were examined, and then the binding energy corresponding to the Y3d orbital on the surface of the fluorination-target component was analyzed to determine the bonding state of atoms.

As a result of analyzing changes in the F content depending on the depth while performing sputtering in units of several nm from the surface, it was confirmed that, in the Y₂O₃ coating (produced by atmospheric plasma spraying) before application of the processing method for fluorination, the Y component and the O component were uniformly distributed at 42 and 58 at. %, respectively.

On the other hand, it was confirmed that, in the fluorination-target component to which the processing method for fluorination according to the present disclosure was applied, the F component was detected throughout the coating surface, and maximum F content values of 33, 44, and 36 at. % were shown, and the F content tended to sharply decrease up to a depth of 100 nm, but decreased slowly after a depth of 100 nm, and F contents of 5, 9 and 11 at. % were found near a depth of 500 nm.

The reason why the F content differs depending on the depth is that, on the surface, the concentration of dissociated F radicals in the plasma is high, and thus a chemical reaction occurs quickly, and then the F radicals diffuse and penetrate into the coating through micropores or crack, and thus the chemical reaction rate becomes lower because the concentration of the F radical is low.

Meanwhile, the F content on the coating surface, measured using energy dispersive spectroscopic analysis, increased as the temperature, the number of repetitions and the power increased. As a result of measurement using depth profiling, the F contents were 44 at. % and 36 at. %, which were inconsistent with the F contents (9 at. % and 15 at. %) measured by energy dispersive spectroscopic analysis. However, from the depth profiling results, toward the inside of the coating, the slope at the F content of 15 at. % measured by energy dispersive spectroscopy analysis gently decreased compared to the slope at the F content of 9 at. %, and a depth of about 500 nm showed a F content value of 11 at. %, which was higher than the F content (9 at. %) measured by energy dispersive spectroscopy, indicating changes in the F content were consistent with changes in the F content on the coating surface, measured using energy dispersive spectroscopy.

The difference in the F content between these analysis techniques was believed to be because, as mentioned above, the analysis depth of EDS was relatively deep in the range of at least 1 μm, whereas the analysis depth of XPS was about 1 nm (the components of the local surface were analyzed). In addition, as a result of analyzing the Y3d orbital of the Y₂O₃ coating produced by atmospheric plasma spraying, two peaks corresponding to Y—O single bonds could be found at 1585 eV and 1567 eV. This was consistent with the report that all the binding energies of the Y3d orbital are composed of a pair of two binding energies caused by Y3d5 and Y3d3, the intensity ratio is 3:2, and the binding energy difference is 2 eV.

In addition, as a result of performing the same analysis for the Y₂O₃ coating produced by atmospheric plasma spraying and having the YOF fluoride layer formed thereon by the processing method for fluorination, four peaks could be identified in all the Y3d orbitals. As a result of performing analysis based on the Y, O and F components identified using the depth profile and EDS, it could be confirmed that the two peaks except for the peak corresponding to the Y—O bond were the Y—F bonds, indicating that the Y—O bonds shifted to the Y—F bonds having higher binding energy while the Y₂O₃ coating produced by atmospheric plasma spraying reacted with the F component to produce the YOF fluoride layer.

Electronegativity refers to a measure of the tendency of an atom to attract electrons to become a negative ion. In general, it is known that, as the electronegativity of an element increases, the binding energy of the element increases. Since the electronegativity of the F atom is 4, which is higher than the electronegativity (3.5) of the O atom, the binding energy of the Y—F bond is measured in a region where it is higher than the binding energy of the Y—O bond. Thus, it could be demonstrated that, when the Y₂O₃ coating is exposed to the F-based corrosive gas plasma, the Y—O bonds are partially decomposed and react with the F radical to form new Y—F bonds, thereby producing the YOF fluoride layer.

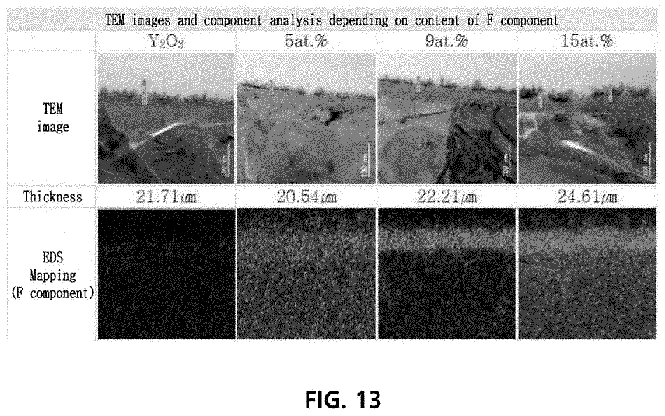

FIG. 13 is a table showing transmission electron microscope images and component analysis of a fluorination-target component depending on the content of F in the processing method for fluorination of a fluorination-target component according to the present disclosure.

Next, as a result of analyzing cross-sectional microstructures using a transmission electron microscope (TEM), it was confirmed that a color corresponding to the F component was detected on all the coating surfaces in the coatings having a YOF fluoride layer with a thickness of early 20 nm, and the color contrast increased as the content of the F component increased.

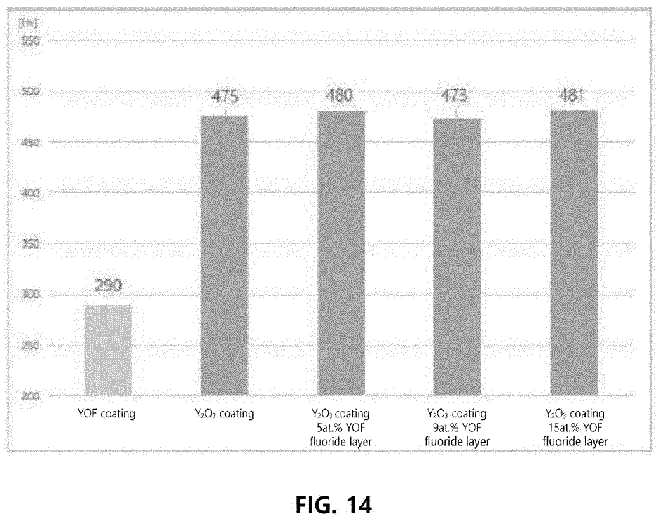

FIG. 14 is a table showing hardness analysis of a fluorination-target component depending on the content of F in the processing method for fluorination of a fluorination-target component according to the present disclosure.

The fluorination-target component to which the processing method for fluorination according to the present disclosure has been applied includes a YOF fluoride layer compared to the Y₂O₃ coating (produced by atmospheric plasma spraying) present before application of the processing method for fluorination. Vickers Hardness was measured to examine changes in hardness depending on the content of the F component.

Compared to the hardness value (475 Hv) of the Y₂O₃ coating (produced by atmospheric plasma spraying) before application of the processing method for fluorination, the hardness values of all the fluorination-target components including the YOF fluoride layer were within the standard deviation range regardless of the content of the F component.

As confirmed from the results described above, it is believed that, since the thickness of the YOF fluoride layer is very thin (several tens to hundreds of nm), the change in hardness depending on the content of the F component is very insignificant.

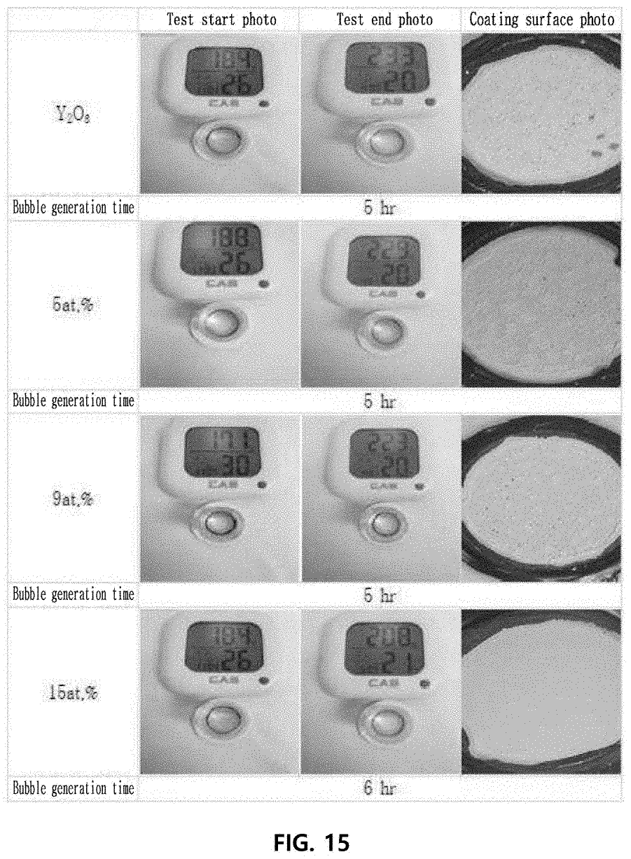

FIG. 15 depicts photographs showing the results of testing the chemical resistance of a fluorination-target component in HCL solution depending on the content of F in the processing method for fluorination of a fluorination-target component according to the present disclosure.

In a semiconductor dry etching process, chemical etching that promotes a chemical reaction with the coating occurs due to the generation of chemically highly active radicals.

In order to test the corrosion resistance of the coating, the coating surface was exposed directly to a 5% hydrochloric acid solution was directly exposed to the coating surface and the time until the coating was etched in the hydrochloric acid was measured. Here, the standard was selected as 3 hours.

In this testing, a fluorination-target component to which the processing method for fluorination has been applied was prepared for each F content.

As a result of analyzing changes in chemical resistance, it was confirmed that, when the content of the F component in the YOF fluoride layer in the fluorination-target component was 5 or 9 at. %, bubbles started to be generated by the reaction of the Y₂O₃ coating (produced by atmospheric plasma spraying) with hydrochloric acid after 5 hours before application of the processing method for fluorination, whereas, when the content of the F component was the highest (15 at. %), bubbles were generated due to the reaction with hydrochloric acid after 6 hours or more.

Therefore, it can be determined that, as the reaction time increases by 1 hour or more at the highest content of the F component, the resistance to corrosive chemicals increases when the content of the F component is a specific value or higher.

As described above, the present disclosure provides the processing method for fluorination of a component according to the present disclosure and a fluorinated component obtained thereby. According to the present disclosure, it is possible to provide a new-concept component fluorination technology capable of fluoridation processing of a component using specific process factors through high-frequency plasma at room temperature and atmospheric pressure for a plasma-resistant coating formed on a semiconductor dry etching system, and it is possible to reduce the cost relatively while applying the present disclosure to a large-area component with high density and high strength and increase productivity by increasing the rate of fluorination (process).

In addition, according to the present disclosure, it is possible to increase productivity by shortening the time of the aging step, which is one of the backup processes being performed in a semiconductor dry etching system, and it is possible to reduce the cost relatively while applying the present disclosure to a large-area component with high density and high strength and increase productivity by increasing the rate of fluorination (process) which is performed in the aging step.

While various embodiments have been described above, it will be understood to those skilled in the art that the embodiments described are by way of example only. Accordingly, the disclosure described herein should not be limited based on the described embodiments.

What is claimed is:

1. A processing method for fluorinating a surface of a fluorination-target component, the method comprising:
a first step of placing the fluorination-target component in a processing chamber having a plasma reaction space;
a second step of introducing a mixed gas into the processing chamber, the mixed gas being composed of a discharge gas selected from among He, Ne, Ar, Kr, and Xe, a fluorine-free reactive gas selected from among O₂, N₂, and air, and a fluorine-containing reactive gas selected from among fluorocarbons, including CF₄, C₂F₆, and C₄F₈, and nitrogen trifluoride (NF₃);
a third step of supplying the mixed gas, introduced into the processing chamber, into the plasma reaction space; and
a fourth step of generating plasma in the plasma reaction space by applying high-frequency power to the processing chamber, and fluorinating the surface of the fluorination-target component by the generated plasma and fluorine-containing radical gas,
wherein an atmosphere in the processing chamber in the first to fourth steps is an atmospheric-pressure atmosphere.

2. The processing method according to claim 1, wherein the third step comprises supplying argon (Ar) as the discharge gas, oxygen (O₂) as the fluorine-free reactive gas, and carbon tetrafluoride (CF₄) as the fluorine-containing reactive gas, and a flow rate ratio of Ar:O₂:CFₐ is 0.1 to 60:0.1 to 10:0.1 to 10.

3. The processing method according to claim 1, wherein the high-frequency power in the fourth step is 300 to 400 W at a frequency of 1 to 100 MHz.

4. The processing method according to claim 1, wherein a temperature inside the processing chamber is room temperature to 400° C.

5. The processing method according to claim 1, wherein the third step and the fourth step are repeated.

6. The processing method according to claim 1, wherein a distance between the fluorination-target component and the plasma is 2 mm to 5 mm.

7. The processing method according to claim 1, wherein a fluoride coating layer on the fluorination-target component is formed to have a thickness of 150 to 200 μm.

8. The processing method according to claim 2, wherein a fluoride coating layer on the fluorination-target component is formed to have a thickness of 150 to 200 μm.

9. The processing method according to claim 3, wherein a fluoride coating layer on the fluorination-target component is formed to have a thickness of 150 to 200 μm.

10. The processing method according to claim 4, wherein a fluoride coating layer on the fluorination-target component is formed to have a thickness of 150 to 200 μm.

11. The processing method according to claim 5, wherein a fluoride coating layer on the fluorination-target component is formed to have a thickness of 150 to 200 μm.

12. The processing method according to claim 6, wherein a fluoride coating layer on the fluorination-target component is formed to have a thickness of 150 to 200 μm.

13. A fluorinated component obtained by the method according to claim 1.

14. A fluorinated component obtained by the method according to claim 2.

15. A fluorinated component obtained by the method according to claim 3.

16. A fluorinated component obtained by the method according to claim 4.

17. A fluorinated component obtained by the method according to claim 5.

18. A fluorinated component obtained by the method according to claim 6.
